(19) United States
(12) Patent Application Publication
(10) Pub. No.: US 2024/0239585 A1
(43) Pub. Date: Jul. 18, 2024

(54) TOP COVER DRAINAGE STRUCTURE FOR LIQUID COOLING BOX BODY OF DATA ROOM

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/402,353

(22) Filed: Jan. 2, 2024

(30) Foreign Application Priority Data
Jan. 12, 2023 (CN) 202310041626.6

(51) Int. Cl. B65D 81/26; B65D 43/16; B65D 51/24

(52) U.S. Cl. CPC B65D 81/261; B65D 43/163; B65D 51/24

(57) ABSTRACT

The present disclosure discloses a top cover drainage structure for a liquid cooling box body of a data room, which at least includes a box body and a top cover. One side of the top cover is hinged with the box body and can cover an opening of the box body. The top cover drainage structure for the liquid cooling box body of the data room also includes a sealing component and a drainage component, where the sealing component is detachably connected to the drainage component, and the sealing component and the drainage component are respectively arranged on the top cover and the box body. When the drainage component is connected to the sealing component, a liquid inside the sealing component flows into the drainage component.

### CROSS REFERENCE TO RELATED APPLICATION

This application claims priority to Chinese Patent Application No. 202310041626.6, titled “TOP COVER DRAINAGE STRUCTURE FOR LIQUID COOLING BOX BODY OF DATA ROOM” and filed to the China National Intellectual Property Administration on Jan. 12, 2023, the entire contents of which are incorporated herein by reference.

### TECHNICAL FIELD

The present disclosure relates to the field of a liquid cooling box body, and more particularly, to a top cover drainage structure for the liquid cooling box body of a data room.

### BACKGROUND

Modern data centers undertake a large amount of data computation and storage, which requires increasingly higher system performance stability. To provide higher energy efficiency to meet needs for business development, heat dissipation of servers and even data rooms has become crucial. As is well known, if the heat dissipation is poor, high temperature not only reduces operating stability of chips, but also generates excessive thermal stress due to temperature difference between internal environment and external environment of modules, which adversely affects electrical performance, operating frequency, mechanical strength, and reliability of the chips.

Compared to traditional air conditioning systems, the most popular liquid cooling technology in the current industry is more advantageous in solving the problem of “heat dissipation of data centers with high heat density”. This liquid cooling technology is quicker in temperature reduction and is lower in energy consumption, and is most friendly to environment.

Liquid cooling refers to a cooling method that uses a liquid with higher specific heat capacity as a working fluid for heat transfer to meet needs for heat dissipation of IT equipment such as servers. Common liquid cooling technologies include immersion cooling, spray cooling, and cold plate cooling.

To ensure normal operation of a liquid cooling box body, it is required to ensure airtightness of the box body. This is because leakage of the liquid cooling box body may cause damage to key components such as chips, and also may cause serious damage to the liquids inside the box body, thus having severe consequences.

An applicant of this patent application has found through research on existing technologies that when there is too much liquid in the liquid cooling box body, after the top cover is opened, the liquid may flow to outer walls of the box body and ground due to tilting, thereby causing pollution to the data rooms.

### SUMMARY

Objectives of the present disclosure are to provide a top cover drainage structure for a liquid cooling box body of a data room, which can collect and discharge a liquid on a top cover when the top cover is opened and flipped, thereby avoiding having a negative effect on environments of the data room.

To achieve the above objectives, the present disclosure provides a top cover drainage structure for a liquid cooling box body of a data room, which at least includes a box body and a top cover. One side of the top cover is hinged with the box body and can cover an opening of the box body. The top cover drainage structure for the liquid cooling box body of the data room may also include a sealing component and a drainage component, where the sealing component is detachably connected to the drainage component, and the sealing component and the drainage component are respectively arranged on the top cover and the box body. When the drainage component is connected to the sealing component, a liquid inside the sealing component flows into the drainage component.

As a further improvement of the above technical solutions, the sealing component includes a sealing block and a drainage channel, where the sealing block is arranged at a bottom of the top cover, and the drainage channel is arranged on the sealing block. The drainage channel is positioned at a hinged part of the sealing block near the top cover, and an end of the drainage channel extends towards an edge of the top cover and penetrates through the edge of the top cover.

As a further improvement of the above technical solutions, a size and a shape of the sealing block fit with the opening of the box body. When the top cover is closed, the sealing block is positioned inside the opening, and an outer wall of the sealing block comes into contact with an inner wall of the opening.

As a further improvement of the above technical solutions, the sealing block is inclined downwards from a center of a central axis of the top cover towards all sides.

As a further improvement of the above technical solutions, part of the sealing block provided with the drainage channel forms a V-shaped structure inclined from two sides to a middle, and the drainage channel is positioned at a bottom of the V-shaped structure.

As a further improvement of the above technical solutions, a runner is arranged along a length of the sealing block, where the runner is positioned on a side of the sealing block near the top cover, and a joint between a side of the sealing block far away from the top cover and the runner is arc-shaped.

As a further improvement of the above technical solutions, the drainage component includes a drainage pipeline, a drainage mounting rack, and a drainage box. Two ends of the drainage pipeline are respectively interconnected to the drainage channel and the drainage box, where the drainage mounting rack is arranged on the box body and is configured to place the drainage box.

As a further improvement of the above technical solutions, a visible window is arranged on the top cover, and the sealing block is annularly arranged around the visible window.

As can be seen from the technical solutions provided in the present disclosure, isolation between the top cover and the box body is increased by providing the sealing component on the top cover, making it impossible for inside of the box body to be directly interconnected to outside, thereby reducing possibility of outflow of the liquid.

Furthermore, the sealing component is detachably connected to the drainage component arranged on the box body, such that when the top cover is flipped, the liquid remaining on a sealing structure is discharged through the drainage component, which prevents the liquid from spilling or flowing to the ground, thereby avoiding having a negative effect on environments of the data room.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a sealing component according to an embodiment of the present disclosure;

FIG. 2 is a schematic structural diagram of a runner according to an embodiment of the present disclosure; and

FIG. 3 is a schematic structural diagram of a drainage component according to an embodiment of the present disclosure.

Reference numerals in the accompanying drawings: box body 1; top cover 2; sealing block 3; runner 31; visible window 4; drainage channel 5; drainage pipeline 6; drainage mounting rack 7; drainage box 8; and pipeline support 9.

### DETAILED DESCRIPTION

Detailed description of the embodiments of the present disclosure will further be made below with reference to the accompanying drawings to make the above objectives, technical solutions and advantages of the present disclosure more apparent. Terms such as “upper” , “above” , “lower” , “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” maybe a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

Modern data centers undertake a large amount of data computation and storage, which requires increasingly higher system performance stability. To provide higher energy efficiency to meet needs for business development, heat dissipation of servers and even data rooms has become crucial. As is well known, if the heat dissipation is poor, high temperature not only reduces operating stability of chips, but also generates excessive thermal stress due to temperature difference between internal environment and external environment of modules, which adversely affects electrical performance, operating frequency, mechanical strength, and reliability of the chips.

Compared to traditional air conditioning systems, the most popular liquid cooling technology in the current industry is more advantageous in solving the problem of “heat dissipation of data centers with high heat density”. This liquid cooling technology is quicker in temperature reduction and is lower in energy consumption, and is most friendly to environment. Liquid cooling refers to a cooling method that uses a liquid with higher specific heat capacity as a working fluid for heat transfer to meet needs for heat dissipation of IT equipment such as servers. Common liquid cooling technologies include immersion cooling, spray cooling, and cold plate cooling.

To ensure normal operation of a liquid cooling box body, it is required to ensure airtightness of the box body. This is because leakage of the liquid cooling box body may cause damage to key components such as chips, and also may cause serious damage to the liquids inside the box body, thus having severe consequences.

In the existing embodiments, when the top cover is opened, the liquid in the liquid cooling box body may flow to outer walls of the box body and ground along inclined parts of the top cover, thereby causing pollution to the data rooms. Therefore, there is an urgent need for a top cover drainage structure for a liquid cooling box body of a data room, which can collect and discharge the liquid on the top cover when the top cover is opened and flipped, to avoid having a negative effect on environments of the data room.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

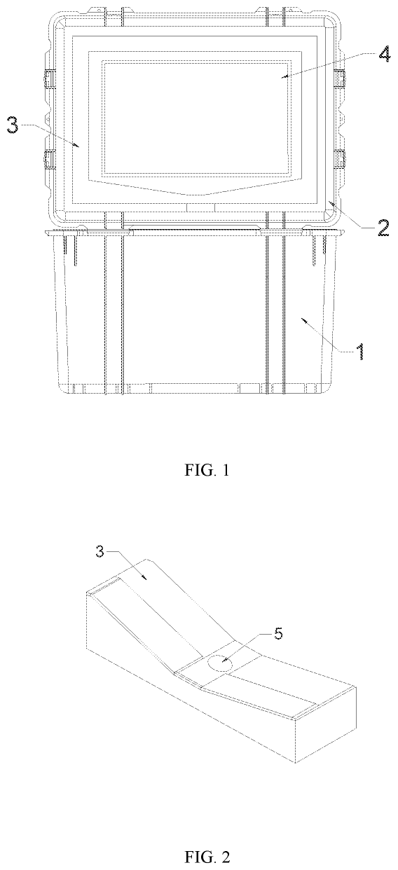

In an implementable embodiment, as shown in FIG. 1 and FIG. 2, a top cover drainage structure for a liquid cooling box body of a data room may at least include a box body 1 and a top cover 2. The top cover 2 can cover an opening of the box body 1. To ensure airtightness of the liquid cooling box body, a sealing structure is generally arranged on the top cover 2. When the top cover 2 is closed, the sealing structure may be soaked into the liquid in the box. As a result, when the top cover 2 is opened, the liquid on the sealing structure cannot flow into box body 1 in time. During the rotation of the top cover 2, the liquid may be brought out by the sealing structure and spills or flows to the outer walls of the box body and the ground, thus polluting the environments of the data room. To solve this problem, the top cover drainage structure for the liquid cooling box body of the data room of the present disclosure may also include a sealing component and a drainage component. The sealing component is detachably connected to the drainage component, and the sealing component and the drainage component are respectively arranged on the top cover 2 and the box body 1. When the drainage component is connected to the sealing component, the liquid inside the sealing component may flow into the drainage component.

Specifically, the box body 1 is a hollow structure with an opening facing upwards to ensure that a server can be placed in the box body 1. The box body 1 is filled with non-conducting liquid, which immerses the server and cools the server. A size of the top cover 2 matches the box body 1, and the top cover 2 can rotate above the opening of the box body 1. When the top cover 2 comes into contact with the box body 1, the top cover 2 can cover the opening of the box body 1 to prevent the liquid from flowing out of the box body 1.

In the solutions of the present disclosure, the sealing component includes a sealing block 3, which is positioned at the bottom of the top cover 2. A size and a shape of the sealing block 3 fit with the opening of the box body 1. Specifically, when the opening is circular, the sealing block 3 is shaped like a circular ring; and when the opening is square, the sealing block 3 is shaped like a square ring. In this way, when the top cover 2 is closed, the sealing block 3 can be positioned inside the opening, and an outer wall of the sealing block 3 comes into contact with an inner wall of the opening, such that isolation between the top cover 2 and the box body 1 is increased, making it impossible for inside of the box body 1 to be directly interconnected to outside, thereby reducing possibility of outflow of the liquid.

In practical applications, to prevent the liquid from directly falling from the box body 1 during the flipping process of the top cover 2 and to ensure the liquid to slide along a direction of the sealing block 3 towards the top cover 2, the sealing block 3 maybe inclined downwards from a center towards all sides. That is, a top of an inclined direction of the sealing block 3 is the center of the top cover 2. In this way, when the top cover 2 is opened, some liquid on the inner wall of the sealing block 3 may directly fall into the box body 1 under the action of gravity, and rest of the liquid may flow to the sealing block 3 at the bottom.

The sealing component also includes a drainage channel 5. As shown in FIG. 2, the drainage channel 5 is positioned at a hinged part of the sealing block 3 near the top cover 2, and the drainage channel 5 extends towards a direction of an edge of the top cover 2 and penetrates through a side wall of the top cover 2. That is, the drainage channel 5 can interconnect the sealing block 3 to the outside. Specifically, when the top cover 2 is flipped, the liquid remaining on the sealing block 3 may flow along an inclined surface of the sealing block 3 and flow to the hinged part of the sealing block 3 near the top cover 2. That is, when the top cover 2 is opened and rotated, the liquid may flow to a bottom part of the sealing block 3 under the action of gravity, and finally may flow out of the top cover 2 through the drainage channel 5.

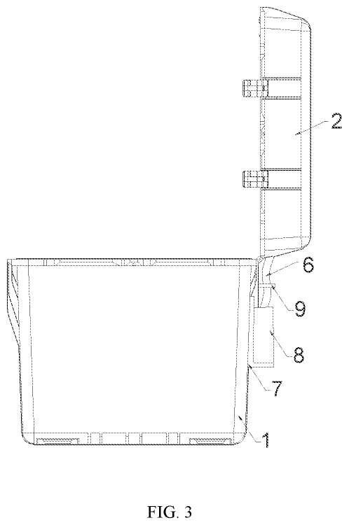

As shown in FIG. 3, the drainage component includes a drainage pipeline 6, a drainage mounting rack 7, and a drainage box 8. One end of the drainage pipeline 6 can be connected to the side wall of the top cover 2 and interconnected to the drainage channel 5 and other end of the drainage pipeline 6 is connected to the drainage box 8. The drainage mounting rack 7 is arranged on the box body 1, and the drainage box 8 is placed on the drainage mounting rack 7. Specifically, when it is required to open the top cover 2, two ends of the drainage pipeline 6 maybe connected to the side wall of the top cover 2 and the drainage box 8 respectively, such that the liquid that enters the drainage channel 5 due to flipping of the top cover 2 can flow, through the drainage pipeline 6, into the drainage box 8. In this way, the liquid remaining on the sealing block 3 is discharged, such that it is avoidable that the liquid spills or flows to the ground of the data room due to the flipping of the top cover 2. In practical applications, when there is too much liquid in the drainage box 8, the operation and maintenance personnel may dismantle the drainage pipeline 6 from the drainage box 8, and remove the drainage box 8 from the drainage mounting rack 7 for replacement.

It is to be pointed out that to prevent the liquid from causing adverse effects on the drainage box 8 and the drainage pipeline 6, corrosion-resistant materials should be selected for the drainage box 8 and the drainage pipeline 6. Specifically, when hydrofluoric acid is used as the coolant liquid in the box body 1, the drainage box 8 and the drainage pipeline 6 maybe made of reinforced polypropylene (RPP) materials.

In an implementable embodiment, to ensure all the liquid on the sealing block 3 to flow into the drainage channel 5, part of the sealing block 3 provided with the drainage channel 5 forms a V-shaped structure inclined from two sides to a middle, and the drainage channel 5 is positioned at the bottom of the V-shaped structure. In this way, the liquid flowing from rest parts of the sealing block 3 to the bottom may flow into the drainage channel 5 due to the inclined structure.

Further, a runner 31 is arranged along a length of the sealing block 3, and the runner 31 is positioned on a side of the sealing block 3 near the top cover 2. The sealing block 3 is slantwise arranged. That is, the runner 31 is positioned at a lower end of the sealing block 3, and a joint between a higher end of the sealing block 3 and the runner 31 is arc-shaped. Such arrangement facilitates the liquid flowing into the runner 31, thus reducing the liquid remaining on the sealing block 3.

In an implementable embodiment, the box body 1 is further provided with a pipeline support 9, and the drainage pipeline 6 penetrates through the pipeline support 9. The drainage pipeline 6 is provided with a clamp plate with a size larger than a diameter of the drainage pipeline 6. The drainage pipeline 6 maybe placed on the pipeline support 9 through the clamp plate, such that when the two ends of the drainage pipeline 6 are connected to the side wall of the top cover 2 and the drainage box 8, the drainage pipeline 6 can still be positioned on the side wall of the box body 1, making it convenient for the operation and maintenance personnel to use.

In an implementable embodiment, the top cover 2 is provided with a visible window 4, which facilitates the operation and maintenance personnel to observe internal conditions of the liquid cooling box body. The visible window 4 is smaller in size than the sealing block 3, and the visible window 4 is positioned inside the annular sealing block 3.

Specifically, due to lower temperature of a coolant liquid stored in the box body 1, materials selected for the visible window 4 need to be able to withstand a certain pressure difference caused by a temperature difference between inside and outside of the box body 1, and a portion of heat from inside the box body 1 maybe absorbed and dissipated into external air.

Further, a surface of the visible window 4 is coated with a hydrophobic coating. The hydrophobic coating comprised of hydrophobic coatings has characteristics such as waterproofing and antifogging, which can ensure that there is no dripping phenomenon inside the visible window 4 after the coolant liquid vaporizes, thus avoiding a situation where interior of the liquid cooling box body cannot be observed during use.

Further, a sealing crimping adhesive is provided at a connection between the visible window 4 and the top cover 2 to enhance sealing performance between the visible window 4 and the top cover 2.

In an implementable embodiment, the top cover 2 is also provided with a handle 4 convenient for the operation and maintenance personnel to flip, where the handle 4 is positioned on a side of the visible window 4, to avoid adversely affecting the observation of the operation and maintenance personnel.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A top cover drainage structure for a liquid cooling box body of a data room, at least comprising a box body (1) and a top cover (2), wherein one side of the top cover (2) is hinged with the box body (1) and can cover an opening of the box body (1); and
the top cover drainage structure for the liquid cooling box body of the data room further comprises a sealing component and a drainage component, wherein the sealing component is detachably connected to the drainage component, and the sealing component and the drainage component are respectively arranged on the top cover (2) and the box body (1); and when the drainage component is connected to the sealing component, a liquid inside the sealing component flows into the drainage component.

2. The top cover drainage structure for the liquid cooling box body of the data room according to claim 1, wherein the sealing component comprises a sealing block (3) and a drainage channel (5), the sealing block (3) is arranged at a bottom of the top cover (2), and the drainage channel (5) is arranged on the sealing block (3); and
the drainage channel (5) is positioned at a hinged part of the sealing block (3) near the top cover (2), and an end of the drainage channel (5) extends towards an edge of the top cover (2) and penetrates through the edge of the top cover (2).

3. The top cover drainage structure for the liquid cooling box body of the data room according to claim 2, wherein a size and a shape of the sealing block (3) fit with the opening of the box body (1); and
when the top cover (2) is closed, the sealing block (3) is positioned inside the opening, and an outer wall of the sealing block (3) comes into contact with an inner wall of the opening.

4. The top cover drainage structure for the liquid cooling box body of the data room according to claim 3, wherein the sealing block (3) is inclined downwards from a center of a central axis of the top cover (2) towards all sides.

5. The top cover drainage structure for the liquid cooling box body of the data room according to claim 2, wherein part of the sealing block (3) provided with the drainage channel (5) forms a V-shaped structure inclined from two sides to a middle, and the drainage channel (5) is positioned at a bottom of the V-shaped structure.

6. The top cover drainage structure for the liquid cooling box body of the data room according to claim 5, wherein a runner (31) is arranged along a length of the sealing block (3); and
the runner (31) is positioned on a side of the sealing block (3) near the top cover (2), and a joint between a side of the sealing block (3) far away from the top cover (2) and the runner (31) is arc-shaped.

7. The top cover drainage structure for the liquid cooling box body of the data room according to claim 1, wherein the drainage component comprises a drainage pipeline (6), a drainage mounting rack (7), and a drainage box (8);
two ends of the drainage pipeline (6) are respectively interconnected to the drainage channel (5) and the drainage box (8); and
the drainage mounting rack (7) is arranged on the box body (1) and is configured to place the drainage box (8).

8. The top cover drainage structure for the liquid cooling box body of the data room according to claim 2, wherein a visible window (4) is arranged on the top cover (2), and the sealing block (3) is annularly arranged around the visible window (4).
